(19) United States
(12) Patent Application Publication
(10) Pub. No.: US 2026/0006369 A1
(43) Pub. Date: Jan. 1, 2026

(54) SYSTEMS AND METHODS FOR DETERMINING A HEADPHONE CUP SHAPE

(71) Applicant: Harman International Industries, Incorporated, Stamford, CT (US)

(72) Inventor: Todd S. WELTI, Thousand Oaks, CA (US)

(73) Assignee: Harman International Industries, Incorporated, Stamford, CT (US)

(21) Appl. No.: 18/756,810

(22) Filed: Jun. 27, 2024

(51) Int. Cl. H04R 1/10; G06F 30/12; G06T 7/50; G06T 7/60

(52) U.S. Cl. CPC H04R 1/1058; G06F 30/12; G06T 7/50; G06T 7/60; G06T 2207/30196

(57) ABSTRACT

A method includes the generation of one or more random outlines, the identification of a depth value for each point of a plurality of points associated with each of the one or more randomly generated outlines corresponding to a periauricular-related surface associated with each test subject of a plurality of test subjects, the determination of a plurality of one or more metrics associated with a variance between each of the one or more randomly generated outlines and the periauricular-related surface for each test subject of the plurality of test subjects, and the calculation of a universal headphone cup outline.

### FIELD

The present disclosure relates to the design of a headphone cup shape, and more particularly, to systems and methods for determining the headphone cup shape based on anthropometric data.

### BACKGROUND

The statements in this section merely provide background information related to the present disclosure and may not constitute prior art.

Headphone cups are typically offered to consumers in standard shapes and sizes, albeit different shapes and sizes. The way in which a headphone cup fits for a user correlates to acoustical leakage and sound quality. As such, the standard headphone cup shapes and sizes have inherent acoustical deficiencies because of the many different head shapes and sizes that may not be an ideal match to the standard headphone cups. This mismatch can also result in difficulty adjusting the headphones on the user's head.

The present disclosure addresses these and other issues related to determining a headphone cup shape.

### SUMMARY

This section provides a general summary of the disclosure and is not a comprehensive disclosure of its full scope or all of its features.

The present disclosure provides a method comprising: generating, for each test subject of a plurality of test subjects, one or more random outlines based on a predetermined size-related range associated with a headphone cup shape; identifying, based on a plurality of three-dimensional meshes, a depth value for each point of a plurality of points associated with each of the one or more randomly generated outlines corresponding to a periauricular-related surface associated with each test subject of the plurality of test subjects, wherein each three-dimensional mesh of the plurality of three-dimensional meshes corresponds to a different test subject of the plurality of test subjects; determining, based on the depth value, a plurality of one or more metrics associated with a variance between each of the one or more randomly generated outlines and the periauricular-related surface for each test subject of the plurality of test subjects; and calculating, based on the plurality of the one or more metrics, a universal headphone cup outline; wherein the predetermined range includes a minimum size-related limit of the headphone cup shape and a maximum size-related limit of the headphone cup shape; wherein the one or more randomly generated headphone cup outlines includes at least one headphone cup outline sized to be within the predetermined size-related range; further comprising: determining a value of a second derivative of the at least one headphone cup outline limited within a maximum allowed curvature associated with the predetermined size-related range; wherein the one or more metrics are further associated with a surface flatness value of a headphone cup; wherein the universal headphone cup outline corresponds to the headphone cup associated with a lowest surface flatness value associated with the surface flatness value; and wherein determining the depth value further comprises: displaying each of the plurality of three-dimensional meshes on a display screen, wherein the determination of the depth value is further based on each three-dimensional mesh of the plurality of three-dimensional meshes being located at identical coordinates.

The present disclosure provides a system comprising: a processor configured to: generate, for each test subject of a plurality of test subjects, one or more random outlines based on a predetermined size-related range associated with a headphone cup shape, identify, based on a plurality of three-dimensional meshes, a depth value for each point of a plurality of points associated with each of the one or more randomly generated outlines corresponding to a periauricular-related surface associated with each test subject of the plurality of test subjects, wherein each three-dimensional mesh of the plurality of three-dimensional meshes corresponds to a different test subject of the plurality of test subjects, determine, based on the depth value, a plurality of one or more metrics associated with a variance between each of the one or more randomly generated outlines and the periauricular-related surface for each test subject of the plurality of test subjects, and calculate, based on the plurality of the one or more metrics, a universal headphone cup outline; and a display screen configured to: display each of the plurality of three-dimensional meshes; wherein the predetermined range includes a minimum size-related limit of the headphone cup shape and a maximum size-related limit of the headphone cup shape; wherein the one or more randomly generated headphone cup outlines includes at least one headphone cup outline sized to be within the predetermined size-related range; wherein the processor is further configured to: determine a value of a second derivative of the at least one headphone cup outline limited within a maximum allowed curvature associated with the predetermined size-related range; wherein the one or more metrics are further associated with a surface flatness value of a headphone cup; wherein the universal headphone cup outline corresponds to the headphone cup associated with a lowest surface flatness value associated with the surface flatness value; and wherein the determination of the depth value is further based on each three-dimensional mesh of the plurality of three-dimensional meshes being located at identical coordinates.

The present disclosure provides one or more non-transitory computer-readable media storing processor-executable instructions that, when executed by at least one processor, cause the at least one processor to: generate, for each test subject of a plurality of test subjects, one or more random outlines based on a predetermined size-related range associated with a headphone cup shape; identify, based on a plurality of three-dimensional meshes, a depth value for each point of a plurality of points associated with each of the one or more randomly generated outlines corresponding to a periauricular-related surface associated with each test subject of the plurality of test subjects, wherein each three-dimensional mesh of the plurality of three-dimensional meshes corresponds to a different test subject of the plurality of test subjects; determine, based on the depth value, a plurality of one or more metrics associated with a variance between each of the one or more randomly generated outlines and the periauricular-related surface for each test subject of the plurality of test subjects; and calculate, based on the plurality of the one or more metrics, a universal headphone cup outline; wherein the predetermined range includes a minimum size-related limit of the headphone cup shape and a maximum size-related limit of the headphone cup shape; wherein the one or more randomly generated headphone cup outlines includes at least one headphone cup outline sized to be within the predetermined size-related range; wherein the at least one processor is further caused to: determine a value of a second derivative of the at least one headphone cup outline limited within a maximum allowed curvature associated with the predetermined size-related range; wherein the at least one processor, caused to determine the depth value, is further caused to: display each of the plurality of three-dimensional meshes on a display screen, wherein the determination of the depth value is further based on each three-dimensional mesh of the plurality of three-dimensional meshes being located at identical coordinates; and wherein the one or more metrics are further associated with a surface flatness value of a headphone cup, and wherein the universal headphone cup outline corresponds to the headphone cup associated with a lowest surface flatness value associated with the surface flatness value.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a block diagram illustrating an example computer system in accordance with one or more embodiments of the present disclosure;

FIG. 2 is a diagram illustrating a plurality of anthropometric features and three-dimensional scans associated with a human subject in accordance with one or more embodiments of the present disclosure;

FIG. 3 is a process-flow diagram illustrating an example method for designing a headphone cup shape in accordance with one or more embodiments of the present disclosure;

FIG. 4 is a schematic view associated with the three-dimensional scans depicted in FIG. 2 and in accordance with one or more embodiments of the present disclosure;

FIG. 5 is an example schematic view associated with the three-dimensional scans depicted in FIGS. 2 and 4 in accordance with one or more embodiments of the present disclosure;

FIG. 6 is another example schematic view associated with the three-dimensional scans depicted in FIGS. 2 and 4 in accordance with one or more embodiments of the present disclosure; and

FIG. 7 is a flowchart illustrating an example method for designing the headphone cup shape in accordance with one or more embodiments of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

One or more embodiments of the present disclosure provide systems and methods for designing a headphone cup shape based on anthropometric data. For example, fitment of the headphone cup shape relative to a person's head can affect acoustical leakage and/or sound quality associated with a headphone set. For example, acoustical leakage can correspond to a low frequency response and passive attenuation associated with the person's interaction with the headphone set when positioned on a user's head.

While headphone cup shapes vary (e.g., headphone cup shapes can be different shapes and sizes) to provide effective fitment of the headphone cups to various people's heads, the cup shapes are not designed or optimized for acoustical properties, and as such, acoustical leakage still may occur. One or more embodiments provide improvements to the headphone cup shapes that can facilitate the mitigation of at least acoustical leakage and/or degraded sound quality associated with the headphone set.

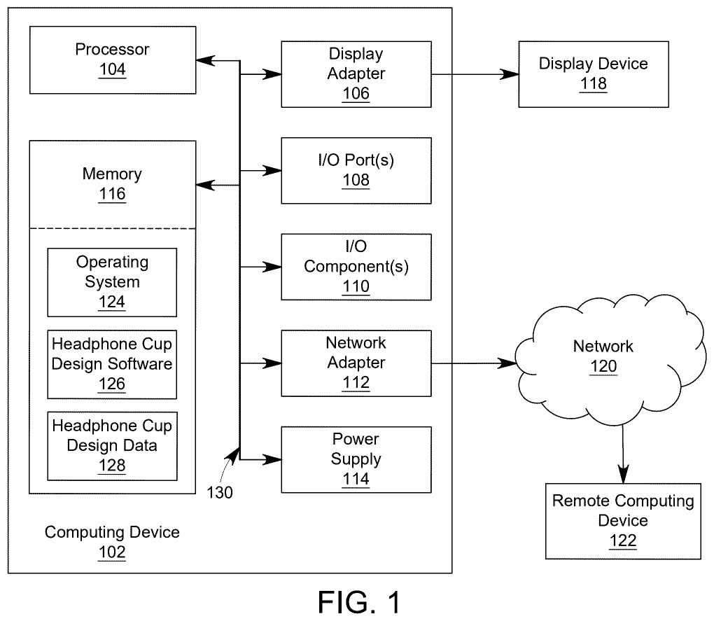

FIG. 1 illustrates an operating environment that facilitates the performance of the one or more systems and methods described herein. More specifically, the systems and methods described herein can be implemented using a computing device 102. For example, the computing device 102 can be a personal computer, a desktop, a laptop, a tablet, a hand-held computer, a server, a workstation, a mainframe, a wearable computer, a supercomputer, or a combination thereof. However, it is understood that the aforementioned examples of the computing device 102 is non-exhaustive and the computing device 102 can be any type of processing or computing device. The computing device 102 generally includes a processor 104, a display adapter 106, one or more input/output port(s) 108, one or more input/output component(s) 110, a network adapter 112, a power supply 114, and a memory 116. However, it is understood that the computing device 102 can include any additional components therein and is not required to include any of the listed components (e.g., the processor 104, the display adapter 106, the one or more input/output port(s) 108, the one or more input/output component(s) 110, the network adapter 112, the power supply 114, and the memory 116).

The processor 104 is configured to provide instructions to the computing device 102 so that the computing device 102 can process one or more tasks including the implementation of a software program to perform one or more operations as described in more detail herein. It is also understood that the computing device 102 may include any number or processors 104 therein. The display adapter 106 can be a graphics card or a video board that provides the computing device 102 with a capability to display content on a display device 118. For example, the display device 118 can be any screen, monitor, and/or light-emitting component associated with any of the personal computer, the desktop, the laptop, the tablet, the hand-held computer, the server, the workstation, the mainframe, the wearable computer, the supercomputer, or a combination thereof. However, it is understood that the aforementioned examples of the display device 118 is non-exhaustive and that the display device 118 can be any type of device capable of providing a visual display.

The input/output port(s) 108 provide a number of interfaces (e.g., sockets) for one or more cables to connect to the computing device 102. It is understood that there may be any number of input/output port(s) 108 on the computing device 102. For example, the input/output port(s) 108 provides a means for the computing device 102 to receive signals and/or data from an external device connected to the computing device 102 via the one or more cables. As another example, the input/output port(s) 108 provide a means for the computing device 102 to send signals and/or data to an external device connected to the computing device 102 via the one or more cables. The input/output component(s) 110 can include one or more components that support the input/output port(s) 108 such as, but not limited to, a switch, a push button, a pressure mat, a float switch, a keypad, a radio receive, or a combination thereof.

The network adapter 112 can be any type of network interface controller that is configured to provide a means for communicating over a network 120 with another computing device, such as a remote computing device 122. For example, the remote computing device 122 can be a user device such as a cellular-phone, a smartphone, a tablet, a laptop, or a combination thereof. The power supply 114 is configured to convert alternating high voltage current (e.g., AC) into direct current (e.g., DC) to provide regulated power to the other components (e.g., the processor 104, the display adapter 106, the one or more input/output port(s) 108, the one or more input/output component(s) 110, the network adapter 112, and the memory 116) of the computing device 102.

Additionally, the memory 116 can be a mass storage device and/or a system memory such as a hard disk drive, a memory card, a solid-state drive, random access memory (RAM), or a combination thereof. The memory 116 is configured to provide storage for instructions and data associated with the operation of the computing device 102. The memory 116 can generally include an operating system 124, headphone cup design software 126, and headphone cup design data 128. For example, the operating system 124 is configured to manage and/or process any of the data and/or instructions associated with the headphone cup design software 126 and/or headphone cup design data 128, as described in more detail herein.

Furthermore, a system bus 130 is also included within the computing device 102 that is configured to couple each of the various components (e.g., the processor 104, the display adapter 106, the one or more input/output port(s) 108, the one or more input/output component(s) 110, the network adapter 112, the power supply 114, and the memory 116) of the computing device 102. It is also understood that each of the components of the computing device 102, and the functionality associated with each of the components of the computing device 102, may be implemented within the remote computing device 122. While the operating environment illustrated within FIG. 1 depicts a particular configuration associated with at least the computing device 102, the network 120, and the remote computing device 122, it is understood that the operating environment may be configured in any way.

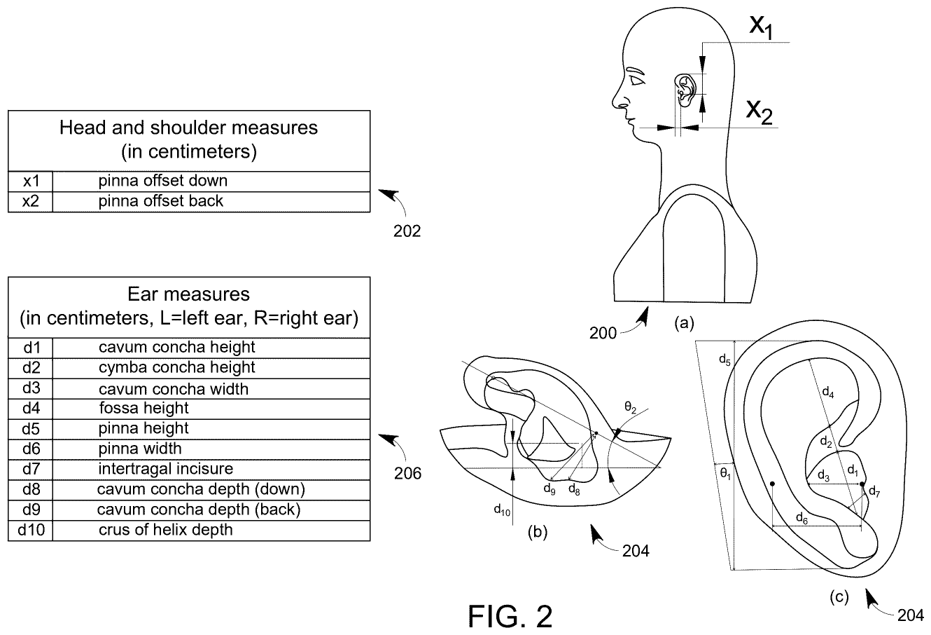

In one or more embodiments, the computing device 102 is configured to perform a headphone cup design process. As an example, the computing device 102 is configured to obtain three-dimensional (3D)-scans of each human subject of a plurality of human subjects (e.g., a 3D-scanned human subject 200 as shown in FIG. 2). It is understood that any number of human subjects (e.g., 340 human subjects) may represent the plurality of human subjects. Each of the 3D-scans may be generated by any scanning mechanism and/or technique and stored by the computing device 102 and each of the human subjects associated with the 3D-scan are selected in a way that mitigates any demographically-based biases such as gender, race, and/or ethnicity in one or more embodiments. The unbiased selection of each of the human subjects, in one or more embodiments, may provide a more accurate representation of the general population of humans. As an additional example, while each of the human subjects may be selected by a computer-generated screening tool, any means of selecting the human subjects may be utilized, such as based on human-decision in one or more embodiments.

It is understood that each of the 3D-scans allows anthropometric data to be determined related to each of the individual human subjects. For example, and as is depicted in FIG. 2, the 3D-scanned human subject 200 can be utilized by the computing device 102 to identify at least one or more anthropometric features for each human subject of the plurality of human subjects and determine a corresponding value for the anthropometric features. More specifically, the 3D-scanned human subject 200 can indicate anthropometric features related to head and shoulder measurements 202 and are associated with a pinna offset [down] (identified as “x1”), a pinna offset [back] (identified as “x2”), or a combination thereof. Each of the x1 and x2 features are illustrated by a respective arrow between two respective anthropometric landmarks as shown in FIG. 2. It is understood that the listing of example measurements included as part of the head and shoulder measurements 202 depicted in FIG. 2 is non-limiting and that the head and shoulder measurements 202 can include any number of head and shoulder-related measurements. It is further understood that the indications of the anthropometric features related to the head and shoulder measurements 202 may be provided on a display screen (e.g., the display device 118).

Additionally, a 3D-scanned ear 204 can indicate anthropometric features related to ear measurements 206 and are associated with a cavum concha height (identified as “d1”), a cymba concha height (identified as “d2”), a cavum concha width (identified as “d3”), a fossa height (identified as “d4”), a pinna height (identified as “d5”), a pinna width (identified as “d6”), an intertragal incisure (identified as “d7”), a cavum concha depth [down](identified as “d8”), a cavum concha depth [back] (identified as “d9”), a crus of helix depth (identified as “d10”), or a combination thereof. Each of the d1-d10 features are illustrated by a respective arrow between two respective anthropometric landmarks as shown in FIG. 2. It is understood that the listing of example measurements included as part of the ear measurements 206 depicted in FIG. 2 is non-limiting and that the ear measurements 206 can include any number of ear-related measurements. It is further understood that the indications of the anthropometric features related to the ear measurements 206 may be provided on the display screen.

It is understood that while the display screen may be provided by the display device 118, the display screen may be any screen associated with the computing device 102, which can be a user device such as a computer or a smart phone, for example. It is further understood that any of the content discussed herein may be displayed on the display screen so that any of the operations described as part of the example process related to design of the optimal headphone cup shape may be viewed by a user (e.g., monitored or assessed by an operator).

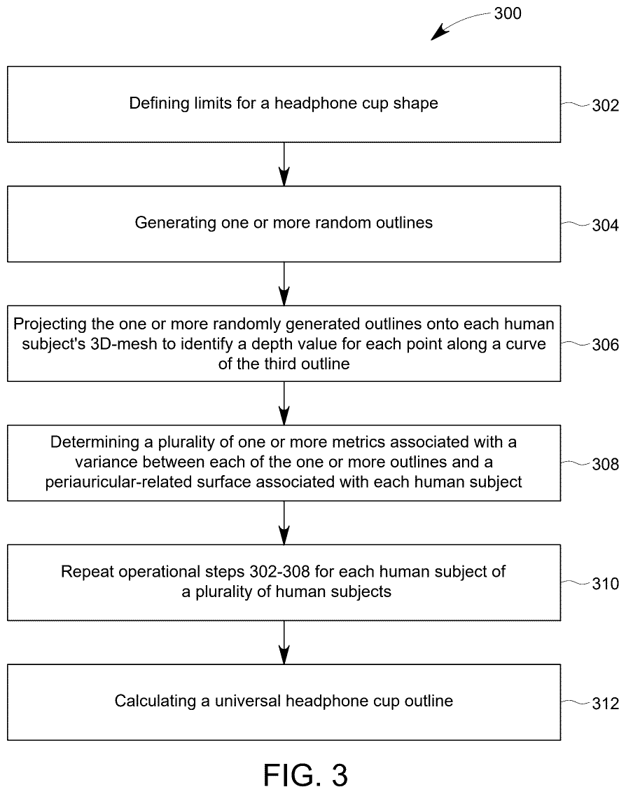

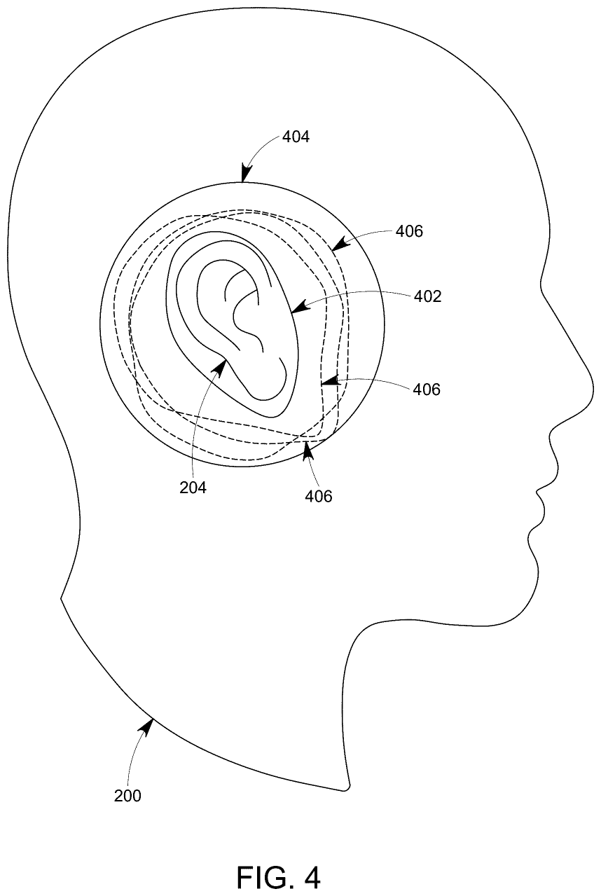

FIG. 3 depicts a process flow illustrating an example process 300 for designing a headphone cup shape (e.g., an optimal or universal headphone cup outline). At operation 302, one or more limits associated with a headphone cup shape are defined. For example, FIG. 4 illustrates a two-dimensional (2D) depiction of the 3D-scanned human subject 200 as it may appear on the display screen indicating various limits as described below. It is understood that the depiction of the 3D-scanned human subject 200 may be displayed on the display screen in the form of any dimensional representation of the 3D-scanned human subject 200.

In one or more embodiments, a lower limit 402 and an upper limit 404 are projected upon the 3D-scanned human subject 200 displayed on the display screen. As an example, the lower limit 402 and the upper limit 404 are representative of the one or more limits defined in operation 302. For example, the lower limit 402 can correspond to a lowest limit that would allow practical application of the headphone cup over the human subject's pinna that corresponds to the 3D-scanned human subject 200. While the lower limit 402 can vary based on mesh data associated with the plurality of human subjects, it is understood that the lower limit 402 is generally applied as a constant limit across all scanned 3D-scanned human subjects 200. For example, the lower limit 402 can be defined based on design principles (e.g., a minimum desired cup size) of the headphone cup. It is also understood that the upper limit 404 can be defined based on design principles (e.g., a maximum desired cup size) of the headphone cup and is consistent across all scanned 3D-scanned human subjects 200. As another example, the upper limit 404 can correspond to a limit that would accommodate at least the 95^{th} percentile of pinna size across a general population of humans. As an additional example, the upper limit 404 and/or the lower limit 402 can be defined by a subset of the general population of humans, the general population of humans, or any sized group of humans. That is, the upper limit 404 and/or the lower limit 402 can be defined based on different thresholds, percentiles, etc.

Returning to FIG. 3, one or more outlines (e.g., one or more randomly generated outlines 406 as should in FIG. 4) are randomly generated at operation 304. For example, a randomly generated outline of the one or more randomly generated outlines 406 can be proposed (e.g., hypothesized) based on the lower limit 402 and the upper limit 404, wherein the randomly generated outline lies entirely within the lower limit 402 and the upper limit 404. As another example, a curve of the proposed randomly generated outline can be smoothed (e.g., caused to be uniform to any particular shape by following a contour at a same distance) based on determining a value corresponding to a second derivate of the proposed randomly generated outline. As yet another example, the determination of the value can be made by mathematically calculating the second derivative of the proposed randomly generated outline in consideration of a limit corresponding to a maximum allowed curvature relative to the lower limit 402 and the upper limit 404 and associated with the displayed 3D-scanned human subject 200. An example equation used to calculate the second derivative of the proposed randomly generated outline is as follows:

$$\frac{{d}^{2} x}{dy} < LimC .$$

As another example, the value of the second derivative of the proposed randomly generated outline can be calculated based on a rate of curvature associated with an X/Y plane of the depicted 3D-scanned human subject 200 to limit at least the value of the second derivative of the proposed randomly generated outline within the maximum allowed curvature defined by LimC. For example, the limitation of at least the value of the second derivative of the proposed randomly generated outline within the maximum allowed curvature exists so that at least the value of the second derivative of the proposed randomly generated outline falls entirely within the lower limit 402 and the upper limit 404. It is understood that the proposal of the randomly generated outline and the determination of the value of the second derivative of the proposed randomly generated outline is a non-limiting example of a process by which an outline may be randomly generated. However, it is further understood that an any number of outlines may be randomly generated by any method. Additionally, it is also understood that the proposal of an outline or the determination of the proposed outline may vary based on biologically physical attributes relating to differences associated with a sizing and/or positioning between a right ear and a left ear of the 3D-scanned human subjects 200.

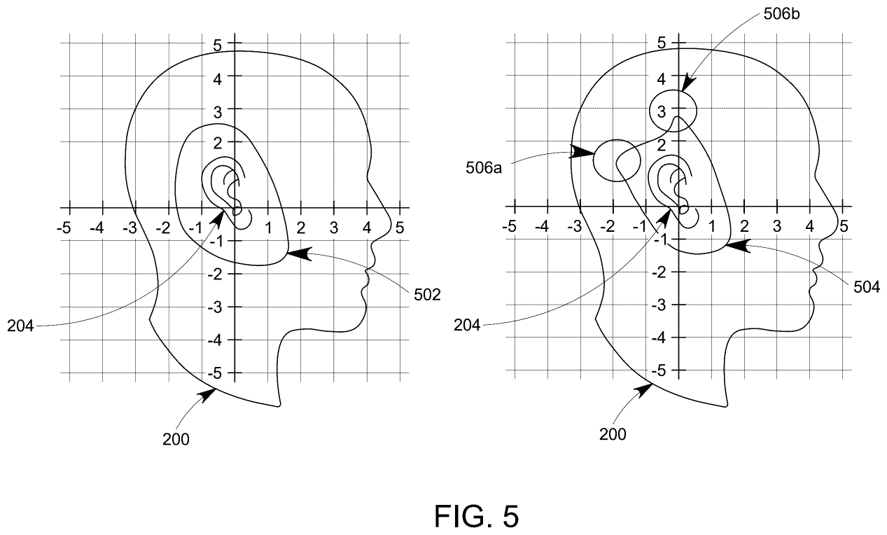

FIG. 5, for example, illustrates a first example outline 502 that may be limited to within the maximum allowed curvature. As another example, an indication that an outline may be limited to within the maximum allowed curvature can be an absence of random protrusions in a shape of the outline. In other words, because the first example outline 502 generally presents as a cohesively smooth shape, the first example outline 502 may be appropriate for commercial manufacturing a headphone cup based on the first example outline 502. As yet another example, and by contrast, a second example outline 504 presents as having a first random protrusion 506a and a second random protrusion 506b that indicates that the second example outline 504 may not be appropriate for commercial manufacturing of a headphone cup based on the second example outline 504.

Returning again to FIG. 3, at operation 306, the one or more randomly generated outlines 406 are projected onto a 3D-mesh associated with a human subject of the plurality of human subjects (e.g., the 3D-scanned human subject 200). As another example, the projection of the one or more randomly generated outlines 406 onto the 3D-mesh allows for an identification of a depth value for each point along a curve of each of the one or more randomly generated outlines 406. As yet another example, the depth value for each point along the curve of each of the one or more randomly generated outlines 406 corresponds to measurements associated with each point in the Z-direction (e.g., into or out of a head of the 3D-scanned human subject 200). For example, a distance of the depth value for each point along the curve of each of the one or more randomly generated outlines 406 corresponds to a first point associated with each point along the curve and a second point against a periauricular-related surface (e.g., a surface including at least a preauricular region and a postauricular region associated with the human subject of the plurality of human subjects) associated with the 3D-scanned human subject 200. As another example, it is understood that ear-related measurements may be made to determine the depth value of any point along any of the one or more randomly generated outlines 406 based on the 3D-scanned ear 204 associated with the 3D-scanned human subject 200.

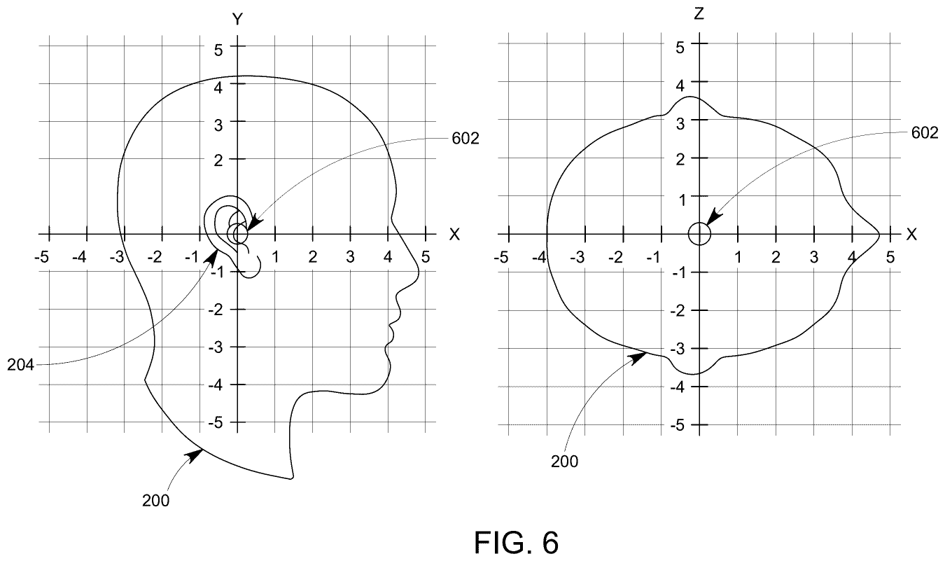

In one or more embodiments, prior to the one or more randomly generated outlines 406 being projected onto the 3D-scanned human subject 200, an ear canal (e.g., an ear canal 602) associated with the 3D-scanned human subject 200 is located at the same coordinates before the depth value is obtained for each point along the third outline. For example, FIG. 6 illustrates a positioning of the 3D-scanned human subject 200 wherein the ear canal 602 is located at coordinates X=0 and Y=0. However, it should be understood that the coordinates can be any coordinates as long as the coordinates are consistent for each 3D-scanned human subject 200.

Returning also to FIG. 3, at operation 308, a plurality of one or more metrics associated with a variance between each of the one or more randomly generated outlines 406 and the periauricular-related surface associated with each 3D-scanned human subject 200 is determined. For example, the plurality of the one or more metrics can include the variance, a maximum deviation, or a combination thereof. As another example, the plurality of the one or more metrics can also include any other metrics related to an amount any of the one or more randomly generated outlines 406 vary in the Z-direction at each point along the curve of any of the one or more randomly generated outlines 406. It is understood that lower metric values correspond to a lower variance between any of the one or more randomly generated outline 406 and the periauricular-related surface (e.g., a flatter periauricular-related surface underneath any of the one or more randomly generated outlines 406) while higher metric values correspond to a higher variance between any of the one or more randomly generated outlines 406 and the periauricular-related surface (e.g., a less flat periauricular-related surface underneath any of the one or more randomly generated outlines 406).

For example, a lower metric value corresponds to an instance wherein the distance between each point along the curve of any of the one or more randomly generated outlines 406 and the periauricular-related surface of the 3D-scanned human subject 200 is minimal. As another example, a higher metric value corresponds to an instance wherein the distance between each point along the curve of any of the one or more randomly generated outlines 406 and the periauricular-related surface of the 3D-scanned human subject 200 is greater. As yet another example, the plurality of the one or more metrics associated with the variance can be determined for each human subject of the plurality of human subjects and/or each ear associated with each human subject of the plurality of human subjects. As a further example, the plurality of the one or more metrics associated with the variance determined for each human subject of the plurality of human subjects and/or each ear associated with each human subject of the plurality of human subjects can be stored by the computing device 102.

At operation 310, operational steps 302-308 are repeated for each human subject of the plurality of human subjects, each of which correspond to a different version of the 3D-scanned human subject 200. Additionally, calculated metrics associated with the repeated operational steps 302-308 are stored by the computing device 102. At operation 312, a universal headphone cup outline is calculated after the plurality of the one or more metrics associated with the variance between the one or more randomly generated outlines 406 and the periauricular-related surface associated with each 3D-scanned human subject 200 is determined. For example, the universal headphone cup outline is representative of an optimal outline shape that may provide the best fitment to a typical human subject.

As an example, the universal headphone cup shape may be selected from the one or more randomly generated outlines 406 corresponding to each human subject of the plurality of human subjects that corresponds to the lowest metric value (e.g., the headphone cup outline curve that corresponds to the flattest result in the Z-dimension) based on the following equation:

$$min [ Variance ( {Z}_{Outline} ) ]$$

In one or more embodiments, the universal headphone cup shape may be determined based on calculating an average outline based on the one or more randomly generated outlines 406 corresponding to each human subject of the plurality of human subjects. Using the calculation associated with the average outline, the headphone cups may be manufactured with a contoured bottom corresponding to an average head contour represented by the 3D-scanned human subject(s) 200. More specifically, the contoured portion of the headphone cup shape may include an indentation behind and below a mastoid of a human ear. It is understood that in the case wherein the average outline is calculated, the universal headphone cup shape may be considered separately or in combination with the contoured headphone cups. Additionally, based on the 3D-scans 200 stored in the computing device 102, multiple headphone cup shapes may be manufactured. In one or more embodiments, different headphone cup sizes determined as optimal (e.g., minimized acoustic leakage) for males, females, and/or children can be manufactured.

However, it is understood that regardless of the manner in which the universal headphone cup shape is calculated, and regardless of the demographic of the human subjects, the outline corresponding to the least variation in the Z-axis (e.g., the flattest outline associated with the periauricular-related surface associated with each 3D-scanned human subject 200) is most likely the best outline curve in one or more embodiments. It is also understood that a headphone driver need not be irregularly shaped to match the headphone cups, although headphone cup shapes that are more circular than oval are desirable in one or more embodiments.

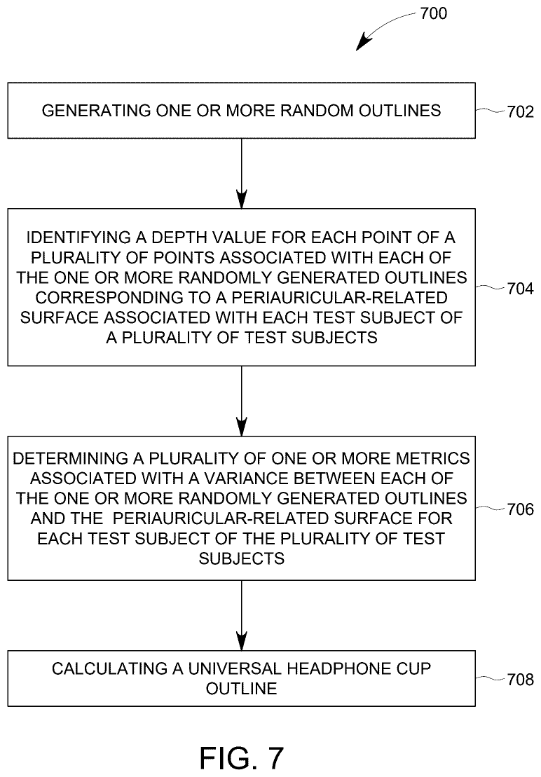

FIG. 7 is a flowchart illustrating an example method 700 for designing a headphone cup shape. At operation 702, one or more randomly generated outlines (e.g., the one or more randomly generated outlines 406) is generated for each test subject of a plurality of test subjects (e.g., each human subject of a plurality of human subjects). For example, the one or more randomly generated outlines is generated based on a predetermined size-related range associated with a headphone cup shape. As another example, the predetermined range includes a minimum size-related limit (e.g., the lower limit 402) of the headphone cup shape and a maximum size-related limit (e.g., the upper limit 404) of the headphone cup shape. As yet another example, the one or more randomly generated headphone cup outlines includes at least one headphone cup outline sized to be within the predetermined size-related range.

At operation 704, a depth value for each point of a plurality of points associated with each of the one or more randomly generated outlines corresponding to a periauricular-related surface associated with each test subject of the plurality of test subjects is identified. As an example, the identification of the depth value for each point of the plurality of points is based on a plurality of three-dimensional meshes (e.g., the 3D-scanned human subject 200). For example, each three-dimensional mesh of the plurality of three-dimensional meshes corresponds to a different test subject of the plurality of test subjects. As another example, each of the plurality of three-dimensional meshes are displayed on a display screen. As yet another example, the determination of the depth value is further based on each three-dimensional mesh of the plurality of three-dimensional meshes being located at identical coordinates.

At operation 706, a plurality of one or more metrics associated with a variance between each of the one or more randomly generated outlines and the periauricular-related surface for each test subject of the plurality of test subjects is determined. For example, the plurality of the one or more metrics is determined based on the depth value as described in more detail herein. As another example, the one or more metrics are further associated with a surface flatness value of a headphone cup as described in more detail herein.

At operation 708, a universal headphone cup outline is calculated. For example, the universal headphone cup outline is calculated based on the plurality of the one or more metrics as described in more detail herein. As another example, the universal headphone cup outline corresponds to the headphone cup associated with a lowest surface flatness value associated with the surface flatness value. In one or more embodiments, a value of a second derivative of the at least one headphone cup outline limited within a maximum allowed curvature associated with the predetermined size-related range is determined.

Thus, one or more examples of the present disclosure provides a means for designing a headphone cup shape that is determined to be a universally optimal headphone cup shape based on anthropometric data associated with a plurality of demographically-diverse human subjects as described in more detail herein.

Based on the foregoing, the following provides a general overview of the present disclosure and is not a comprehensive summary. In a first one or more embodiments A1, a method comprising the generation, for each test subject of a plurality of test subjects, one or more random outlines based on a predetermined size-related range associated with a headphone cup shape is disclosed. A depth value for each point of a plurality of points associated with each of the one or more randomly generated outlines corresponding to a periauricular-related surface associated with each test subject of the plurality of test subjects is identified based on a plurality of three-dimensional meshes, wherein each three-dimensional mesh of the plurality of three-dimensional meshes corresponds to a different test subject of the plurality of test subjects. A plurality of one or more metrics associated with a variance each of the one or more randomly generated between the headphone cup outlines and the periauricular-related surface for each test subject of the plurality of test subjects is determined based on the depth value. A universal headphone cup outline is calculated based on the plurality of the one or more metrics.

In a second one or more embodiments A2, which may include the first one or more embodiments A1, the predetermined range includes a minimum size-related limit of the headphone cup shape and a maximum size-related limit of the headphone cup shape. In a third one or more embodiments A3, which may include any combination of the first through second one or more embodiments A1-A2, the one or more randomly generated headphone cup outlines includes at least one headphone cup outline sized to be within the predetermined size-related range.

In a fourth one or more embodiments A4, which may include any combination of the first through third one or more embodiments A1-A3, a value of a second derivative of the at least one headphone cup outline limited within a maximum allowed curvature associated with the predetermined size-related range is determined. In a fifth one or more embodiments A5, which may include any combination of the first through fourth one or more embodiments A1-A4, the one or more metrics are further associated with a surface flatness value of a headphone cup. In a sixth one or more embodiments A6, which may include any combination of the first through fifth one or more embodiments A1-A5, the universal headphone cup outline corresponds to the headphone cup associated with a lowest surface flatness value associated with the surface flatness value. In a seventh one or more embodiments A7, which may include any combination of the first through sixth one or more embodiments A1-A6, the determination of the depth value further comprises the display each of the plurality of three-dimensional meshes on a display screen, wherein the determination of the depth value is further based on each three-dimensional mesh of the plurality of three-dimensional meshes being located at identical coordinates.

In an eighth one or more embodiments A8, which may include any combination of the first through seventh one or more embodiments A1-A7, a system comprising a processor is configured to generate, for each test subject of a plurality of test subjects, one or more random outlines based on a predetermined size-related range associated with a headphone cup shape. Identify a depth value for each point of a plurality of points associated with each of the one or more randomly generated outlines corresponding to a periauricular-related surface associated with each test subject of the plurality of test subjects based on a plurality of three-dimensional meshes, wherein each three-dimensional mesh of the plurality of three-dimensional meshes corresponds to a different test subject of the plurality of test subjects. Determine a plurality of one or more metrics associated with a variance between each of the one or more randomly generated outlines and the periauricular-related surface for each test subject of the plurality of test subjects based on the depth value. Calculate a universal headphone cup outline based on the plurality of the one or more metrics. The system also comprises a display screen configured to display each of the plurality of three-dimensional meshes. In a ninth one or more embodiments A9, which may include any combination of the first through eighth one or more embodiments A1-A8, the predetermined range includes a minimum size-related limit of the headphone cup shape and a maximum size-related limit of the headphone cup shape. In a tenth one or more embodiments A10, which may include any combination of the first through ninth one or more embodiments A1-A9, the one or more randomly generated headphone cup outlines includes at least one headphone cup outline sized to be within the predetermined size-related range.

In an eleventh one or more embodiments A11, which may include any combination of the first through tenth one or more embodiments A1-A10, the processor is further configured to determine a value of a second derivative of the at least one headphone cup outline limited within a maximum allowed curvature associated with the predetermined size-related range. In a twelfth one or more embodiments A12, which may include any combination of the first through eleventh one or more embodiments A1-A11, the one or more metrics are further associated with a surface flatness value of a headphone cup. In a thirteenth one or more embodiments A13, which may include any combination of the first through twelfth one or more embodiments A1-A12, the universal headphone cup outline corresponds to the headphone cup associated with a lowest surface flatness value associated with the surface flatness value. In a fourteenth one or more embodiments A14, which may include any combination of the first through thirteenth one or more embodiments A1-A13, the determination of the depth value is further based on each three-dimensional mesh of the plurality of three-dimensional meshes being located at identical coordinates.

In a fifteenth one or more embodiments A15, which may include any combination of the first through fourteenth one or more embodiments A1-A14, one or more non-transitory computer-readable media storing processor-executable instructions that, when executed by at least one processor, cause the at least one processor to generate, for each test subject of a plurality of test subjects, one or more random outlines based on a predetermined size-related range associated with a headphone cup shape. Identify a depth value for each point of a plurality of points associated with each of the one or more randomly generated outlines corresponding to a periauricular-related surface associated with each test subject of the plurality of test subjects based on a plurality of three-dimensional meshes, wherein each three-dimensional mesh of the plurality of three-dimensional meshes corresponds to a different test subject of the plurality of test subjects. Determine a plurality of one or more metrics associated with a variance between each of the one or more randomly generated outlines and the periauricular-related surface for each test subject of the plurality of test subjects based on the depth value. Calculate a universal headphone cup outline based on the plurality of the one or more metrics. In a sixteenth one or more embodiments A16, which may include any combination of the first through fifteenth one or more embodiments A1-A15, the predetermined range includes a minimum size-related limit of the headphone cup shape and a maximum size-related limit of the headphone cup shape. In a seventeenth one or more embodiments A17, which may include any combination of the first through sixteenth one or more embodiments A1-A16, the one or more randomly generated headphone cup outlines includes at least one headphone cup outline sized to be within the predetermined size-related range.

In an eighteenth one or more embodiments A18, which may include any combination of the first through seventeenth one or more embodiments A1-A17, the at least one processor is further caused to determine a value of a second derivative of the at least one headphone cup outline limited within a maximum allowed curvature associated with the predetermined size-related range. In a nineteenth one or more embodiments A19, which may include any combination of the first through eighteenth one or more embodiments A1-A18, the at least one processor, caused to determine the depth value, is further caused to display each of the plurality of three-dimensional meshes on a display screen, wherein the determination of the depth value is further based on each three-dimensional mesh of the plurality of three-dimensional meshes being located at identical coordinates. In a twentieth one or more embodiments A20, which may include any combination of the first through nineteenth one or more embodiments A1-19, the one or more metrics are further associated with a surface flatness value of a headphone cup, and wherein the universal headphone cup outline corresponds to the headphone cup associated with a lowest surface flatness value associated with the surface flatness value.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method comprising:
generating, for each test subject of a plurality of test subjects, one or more random outlines based on a predetermined size-related range associated with a headphone cup shape;
identifying, based on a plurality of three-dimensional meshes, a depth value for each point of a plurality of points associated with each of the one or more randomly generated outlines corresponding to a periauricular-related surface associated with each test subject of the plurality of test subjects, wherein each three-dimensional mesh of the plurality of three-dimensional meshes corresponds to a different test subject of the plurality of test subjects;
determining, based on the depth value, a plurality of one or more metrics associated with a variance between each of the one or more randomly generated outlines and the periauricular-related surface for each test subject of the plurality of test subjects; and
calculating, based on the plurality of the one or more metrics, a universal headphone cup outline.

2. The method of claim 1, wherein the predetermined range includes a minimum size-related limit of the headphone cup shape and a maximum size-related limit of the headphone cup shape.

3. The method of claim 1, wherein the one or more randomly generated headphone cup outlines includes at least one headphone cup outline sized to be within the predetermined size-related range.

4. The method of claim 3, further comprising:
determining a value of a second derivative of the at least one headphone cup outline limited within a maximum allowed curvature associated with the predetermined size-related range.

5. The method of claim 1, wherein the one or more metrics are further associated with a surface flatness value of a headphone cup.

6. The method of claim 5, wherein the universal headphone cup outline corresponds to the headphone cup associated with a lowest surface flatness value associated with the surface flatness value.

7. The method of claim 1, wherein determining the depth value further comprises:
displaying each of the plurality of three-dimensional meshes on a display screen, wherein the determination of the depth value is further based on each three-dimensional mesh of the plurality of three-dimensional meshes being located at identical coordinates.

8. A system comprising:
a processor configured to:
generate, for each test subject of a plurality of test subjects, one or more random outlines based on a predetermined size-related range associated with a headphone cup shape,
identify, based on a plurality of three-dimensional meshes, a depth value for each point of a plurality of points associated with each of the one or more randomly generated outlines corresponding to a periauricular-related surface associated with each test subject of the plurality of test subjects, wherein each three-dimensional mesh of the plurality of three-dimensional meshes corresponds to a different test subject of the plurality of test subjects,
determine, based on the depth value, a plurality of one or more metrics associated with a variance between each of the one or more randomly generated outlines and the periauricular-related surface for each test subject of the plurality of test subjects, and
calculate, based on the plurality of the one or more metrics, a universal headphone cup outline; and
a display screen configured to:
display each of the plurality of three-dimensional meshes.

9. The system of claim 8, wherein the predetermined range includes a minimum size-related limit of the headphone cup shape and a maximum size-related limit of the headphone cup shape.

10. The system of claim 8, wherein the one or more randomly generated headphone cup outlines includes at least one headphone cup outline sized to be within the predetermined size-related range.

11. The system of claim 10, wherein the processor is further configured to:
determine a value of a second derivative of the at least one headphone cup outline limited within a maximum allowed curvature associated with the predetermined size-related range.

12. The system of claim 8, wherein the one or more metrics are further associated with a surface flatness value of a headphone cup.

13. The system of claim 12, wherein the universal headphone cup outline corresponds to the headphone cup associated with a lowest surface flatness value associated with the surface flatness value.

14. The system of claim 8, wherein the determination of the depth value is further based on each three-dimensional mesh of the plurality of three-dimensional meshes being located at identical coordinates.

15. One or more non-transitory computer-readable media storing processor-executable instructions that, when executed by at least one processor, cause the at least one processor to:
generate, for each test subject of a plurality of test subjects, one or more random outlines based on a predetermined size-related range associated with a headphone cup shape and one or more randomly generated headphone cup outlines;
identify, based on a plurality of three-dimensional meshes, a depth value for each point of a plurality of points associated with each of the one or more randomly generated outlines corresponding to a periauricular-related surface associated with each test subject of the plurality of test subjects, wherein each three-dimensional mesh of the plurality of three-dimensional meshes corresponds to a different test subject of the plurality of test subjects;
determine, based on the depth value, a plurality of one or more metrics associated with a variance between each of the one or more randomly generated outlines and the periauricular-related surface for each test subject of the plurality of test subjects; and
calculate, based on the plurality of the one or more metrics, a universal headphone cup outline.

16. The one or more non-transitory computer-readable media of claim 15, wherein the predetermined range includes a minimum size-related limit of the headphone cup shape and a maximum size-related limit of the headphone cup shape.

17. The one or more non-transitory computer-readable media of claim 15, wherein the one or more randomly generated headphone cup outlines includes at least one headphone cup outline sized to be within the predetermined size-related range.

18. The one or more non-transitory computer-readable media of claim 17, wherein the at least one processor is further caused to:
determine a value of a second derivative of the at least one headphone cup outline limited within a maximum allowed curvature associated with the predetermined size-related range.

19. The one or more non-transitory computer-readable media of claim 15, wherein the at least one processor, caused to determine the depth value, is further caused to:
display each of the plurality of three-dimensional meshes on a display screen, wherein the determination of the depth value is further based on each three-dimensional mesh of the plurality of three-dimensional meshes being located at identical coordinates.

20. The one or more non-transitory computer-readable media of claim 19, wherein the one or more metrics are further associated with a surface flatness value of a headphone cup, and wherein the universal headphone cup outline corresponds to the headphone cup associated with a lowest surface flatness value associated with the surface flatness value.
